(19) United States
(12) Patent Application Publication
(10) Pub. No.: US 2016/0047867 A1
(43) Pub. Date: Feb. 18, 2016

(54) SAMPLE HOLDER AND METHOD

(71) Applicant: UB2 Instruments SRL, Mihai Viteazu (RO)

(72) Inventors: Romulus Valeriu Flaviu TURCU, Cluj (RO); Simion SIMON, Cluj-Napoca (RO)

(21) Appl. No.: 14/457,919

(22) Filed: Aug. 12, 2014

(51) Int. Cl. G01R 33/30

(52) U.S. Cl. CPC G01R 33/305

(57) ABSTRACT

A sample holder for use with magic angle spinning NMR and similar magnetic resonance analysis techniques which includes a sample holder sealed by an O-ring and a contact seal. The O-ring seals the sample volume during pressurization whereas the contact seal is active during analysis. The O-ring and the contact seal are disposed so that rotation of a plug selective engages one or both of the seals.

### BACKGROUND

1. Technical Field

The present disclosure relates to sample holders including sample holders which may be used in analysis techniques such as magnetic resonance spectroscopy (MRS), magnetic resonance imaging (MRI) (e.g., magic angle spinning (MAS) nuclear magnetic resonance (NMR)), electron paramagnetic resonance (EPR), dynamic nuclear polarization (DNP), electron nuclear double resonance (ENDOR), etc.

2. Description of the Related Art

Both high resolution magic angle spinning (MAS) nuclear magnetic resonance (NMR) and electron paramagnetic resonance (EPR), as well as the combination of these (dynamic nuclear polarization (DNP) and electron-nuclear double resonance (ENDOR) are used for studying molecular structure and dynamics in samples which may be solid, semi-solid, or a heterogeneous mixture containing multiple phases. These are of particular interest in biophysics, such as protein investigations, catalysis analysis, geochemistry experiments, food preservation investigation and various experiments in medicine.

It is desirable to be able to set the pressure for the sample under investigation. This may involve either lower or higher pressures and temperatures than ambient conditions, and it is desirable to be able to investigate samples under a range of conditions without adversely affecting the sample, and being able to alter these conditions easily.

FIG. 1 illustrates a sample holder for use as a rotor of the type illustrated and described in US2012/0146636. Rotor 20 includes a rotor sleeve (cylinder) 1, a drive (spin) tip 2, bushings 4 and 5, a valve adapter 6, an end plug 7, and a high pressure sealing valve (end cap) 8. Valve adapter 6 has a threaded end portion that inserts into, and screws along, the interior receiving surface of bushing 5. High pressure sealing valve 8 includes a head portion, and a tapered end portion, that screws into the receiving end of valve adapter 6. End plug 7 is positioned on an opposite side of rotor 1 and includes a threaded end that screws through the interior threaded surface below bushing 4. In the instant embodiment, drive tip 2 inserts into the bottom of rotor sleeve 1.

Grooves 14 are machined in rotor sleeve 1 at selected positions along the internal surface at respective ends. Grooves 14 are introduced, e.g., using a diamond mill that creates a rough surface. Bushings 4 and 5 insert into, and screw through, along grooves 14 positioned along the milled surface of rotor sleeve 1. Bushings 4 and 5 are secured in place adjacent the threaded surface, e.g., at respective ends of rotor sleeve 1, in concert with a high-pressure adhesive, which is allowed to cure.

Bushings 4 and 5 form high-pressure seals within rotor sleeve 1 in concert with O-rings 9 positioned above and below bushings 4 and 5 in rotor sleeve 1.

The rotor sleeve 20 has the disadvantage that the O-rings 9 are required to produce a seal at all times during the use of the sleeve. O-rings tend to degrade over time. Since the O-rings of the rotor sleeve 20 are located behind the bushings, it is relatively difficult and expensive to replace the O-rings, and almost impossible to inspect the O-rings to determine when they may require replacement during analysis. Therefore, rotor sleeves of this type tend to fail in an unpredictable manner and their replacement is relatively expensive.

### BRIEF SUMMARY

In an embodiment, a pressurizable sample holder is provided, the sample holder comprising a sample cell having an inner surface defining a sample volume and a plug for maintaining the sample volume under pressure, the sample holder further comprising first and second seals for sealing the sample volume, wherein said first and second seals are formed with said plug, the plug further comprising an inlet, wherein the plug engages with the sample cell so that the first seal seals the sample volume during operational use of the sample holder and the second seal forms a seal when the inlet is in use to pressurize the sample volume.

In an embodiment, two separate seals which are formed by a plug, which facilitate maintaining the seals.

In an embodiment, the plug may be moveable between a first position and a second position, wherein the first seal is engaged when the plug is in the first position and the second seal is engaged when the plug is in the second position.

In an embodiment, reliance on conventional use of dual O-rings to provide an active seal while the sample holder is undergoing operational use (e.g., is undergoing MAS NMR or a similar analytical technique) may be avoided, which facilitates sample holders having more efficient and reliable seals. Avoiding the conventional use of dual O-rings facilitates maintaining environments which were previously not possible where their corrosive nature would affect the integrity of the O-rings such as supercritical CO₂.

In an embodiment, the inner surface of the sample cell may comprise a threaded portion and wherein an outer surface of the plug comprises a complimentary threaded portion, and wherein movement of the plug comprises rotation.

In an embodiment, the inlet may be formed with an inlet aperture formed upstream of the threaded portion of the outer surface of the plug. Upstream may refer to the direction of fluid escaping the sample holder kept in place by the plug.

In an embodiment, the second seal may be engaged when the plug is in the first position.

In an embodiment, the sample holder may have an escape fluid flow for fluid exiting the sample holder through an aperture filled by the plug, in which case the second seal may be situated downstream from the first seal with respect to the escape fluid flow.

In an embodiment, the first seal may be formed between a surface of the plug and the inner surface of the sample cell.

In an embodiment, the second seal may be an O-ring disposed between the inner surface of the sample cell and the plug.

In an embodiment, a receptacle may be formed in the plug.

In an embodiment, the sample cell may be formed as a single machined part.

In an embodiment, the plug may be formed as a single machined part.

In an embodiment, both the sample cell and the plug are each formed as a single integrated part, which may make the parts easier and cheaper to manufacture.

In an embodiment, the sample cell may have a first aperture filled by the plug.

In an embodiment, the sample cell may have a first aperture and a second aperture wherein the first aperture is filled by said plug.

In an embodiment, a system comprises a sample holder as herein described and an injector for delivering a fluid under pressure to the sample volume.

In an embodiment, the plug may include a receptacle at least partially defined by a threaded portion of a surface of the plug and the injector may include a complementary threaded portion for engaging with the threaded portion of the plug.

In at least one embodiments: the sample holders are re-usable; they may be used with high-pressure maintained in the sample volume; alternatively they may be used with low-pressure maintained in the sample volume; they are usable with both low and high temperatures maintained in the sample volume; they may be subjected to microwaves; and may not require a separate loading device; and very little fluid other than that contained in the sample volume need be pressurized or evacuated, which is more efficient than subjecting an additional volume to excess or reduced pressure.

As used herein, “high-pressure” may refer to approximately 150 to 350 bar, or more and “low pressure” may refer to approximately 10³ to 10⁻⁴ mbar, or less.

In an embodiment, a method of preparing a sample volume, comprises: providing a pressurizable sample holder comprising a sample cell having an inner surface defining a sample volume and a plug for maintaining the sample volume under pressure, further comprising: providing first and second seals in the sample holder for sealing the sample volume, wherein said first and second seals are formed with said plug, providing an inlet in the plug; and engaging the plug with the sample cell so that the first seal seals the sample volume during operational use of the sample holder and the second seal forms a seal when the inlet is in use to pressurize the sample volume. In an embodiment, the method comprises moving the plug between a first position and a second position, wherein the first seal is engaged when the plug is in the first position and the second seal is engaged when the plug is in the second position. In an embodiment, the method comprises providing the inner surface of the sample cell with a threaded portion and an outer surface of the plug with a complimentary threaded portion, and wherein said movement of the plug comprises rotation. In an embodiment, the inlet is formed with an inlet aperture formed upstream of the threaded portion of the outer surface of the plug. In an embodiment, the second seal is engaged when the plug is in the first position. In an embodiment, the sample cell and the plug engage through a bayonet connection. In an embodiment, fluid exiting the sample holder flows in an escape fluid flow, wherein the second seal is provided downstream from the first seal with respect to the escape fluid flow. In an embodiment, the first seal is formed between a surface of the plug and the inner surface of the sample cell. In an embodiment, the second seal is provided as an O-ring disposed between the inner surface of the sample cell and the plug. In an embodiment, a receptacle is provided in the plug. In an embodiment, the method comprises forming the sample cell as a single machined part. In an embodiment, the method comprises forming the plug as a single machined part.

In an embodiment, no external loading device is needed to provide a sample under increased or reduced pressure, which facilitates use in different (multiple) type of Magnetic Resonance spectrometers such as MAS NMR, EPR, Dynamic Nuclear Polarization NMR (DNP NMR), and Electron Nuclear Double Resonance (ENDOR). This may enhance the ability to undertake structural and dynamic investigation of solid/liquid/gas mixtures by facilitating replicating the sample conditions.

In an embodiment, a sample holder comprises: a sample cell having an inner surface defining a sample volume; and a plug configured to couple to the sample cell, the plug including: a pressurization inlet; a first sealing surface configured to mate with the sample cell to form an operational seal of the sample holder; and a second sealing surface configured to mate with the sample cell to form a pressurizing seal of the sample holder. In an embodiment, the plug is configured to move between a first position and a second position; the first sealing surface is configured to sealingly mate with the sample cell when the plug is in the first position; and the second sealing surface is configured to sealingly mate with the sample cell when the plug is in the second position. In an embodiment, the inner surface of the sample cell comprises a threaded portion, an outer surface of the plug comprises a complimentary threaded portion, and movement of the plug comprises rotation. In an embodiment, the pressurization inlet has an inlet aperture upstream of the threaded portion of the outer surface of the plug. In an embodiment, the second sealing surface is configured to sealingly mate with the sample cell when the plug is in the first position. In an embodiment, the sample cell and the plug are configured to couple together through a bayonet connection. In an embodiment, the sample holder has an escape fluid flow for fluid exiting the sample holder through an aperture filled by the plug, wherein the second seal is situated downstream from the first seal with respect to the escape fluid flow. In an embodiment, the first sealing surface is a surface of a body of the plug configured to mate with the inner surface of the sample cell. In an embodiment, the plug comprises a body and the second sealing surface comprises an O-ring positioned on the plug body and configured to mate with the inner surface of the sample cell. In an embodiment, the plug has a receptacle. In an embodiment, the sample cell is formed as a single machined part. In an embodiment, a body of the plug is formed as a single machined part. In an embodiment, the sample cell has a first aperture filled by said plug. In an embodiment, the sample cell has a first aperture and a second aperture wherein the first aperture is filled by said plug.

In an embodiment, a system comprises: a sample holder having: a sample cell having an inner surface defining a sample volume; and a plug configured to couple to the sample cell, the plug including: a pressurization inlet; a first sealing surface configured to mate with the sample cell to form an operational seal of the sample holder; and a second sealing surface configured to mate with the sample cell to form a pressurizing seal of the sample holder; and an injector configured to deliver a fluid under pressure to the sample volume via the pressurization inlet. In an embodiment, the plug includes a receptacle at least partially defined by a threaded portion of a surface of the plug, and the injector includes a complementary threaded portion to engaging with the threaded portion of the plug.

In an embodiment, a method comprises: forming a pressurization seal between a pressurization-seal surface of a plug and a sample cell of a sample holder, an inner surface of the sample cell defining a sample volume; pressurizing the sample cell via an inlet in the plug; and forming an operational seal between an operational-seal surface of the plug and the sample cell. In an embodiment, the method comprises moving the plug between a first position and a second position, wherein the operational seal is formed when the plug is in the first position and the pressurization seal is formed when the plug is in the second position. In an embodiment, the method comprising providing the inner surface of the sample cell with a threaded portion and an outer surface of the plug with a complimentary threaded portion, wherein the moving of the plug comprises rotation. In an embodiment, the inlet is formed with an inlet aperture upstream of the threaded portion of the outer surface of the plug. In an embodiment, the pressurization seal is formed when the plug is in the first position. In an embodiment, the sample cell and the plug are coupled together through a bayonet connection. In an embodiment, fluid exiting the sample holder flows in an escape fluid flow, wherein the second seal is provided downstream from the first seal with respect to the escape fluid flow. In an embodiment, the operational seal is formed between a surface of a body of the plug and the inner surface of the sample cell. In an embodiment, the plug comprises a plug body and an O-ring positioned on the body of the plug, and the pressurization seal is formed between the O-ring and the inner surface of the sample cell. In an embodiment, the plug includes a receptacle. In an embodiment, the method comprises forming the sample cell as a single machined part. In an embodiment, the method comprising forming a body of the plug as a single machined part.

### BRIEF DESCRIPTION OF THE SEVERAL VIEWS OF THE DRAWINGS

Embodiments are herein described with reference to the accompanying diagrams in which:

FIG. 1 illustrates a sample holder for use as a rotor of the type illustrated and described in US2012/0146636;

FIG. 2 illustrates a sample holder according to an embodiment and a sealing cell used with the sample holder;

FIG. 3 illustrates a sample holder according to an embodiment;

FIG. 4 illustrates an embodiment of a plug for use with a sample holder of FIG. 3;

FIG. 5 illustrates an embodiment of the sealing cell of FIG. 2;

FIG. 6 illustrates a detail of the sealing cell of FIG. 5;

FIG. 7 illustrates an embodiment of an engagement between the sample holder of FIG. 3 and the sealing cell of FIG. 5;

FIG. 8 illustrates a portion of the sample holder of FIG. 3 during use in a first configuration; and

FIG. 9 illustrates a portion of the sample holder of FIG. 3 during use in a second configuration.

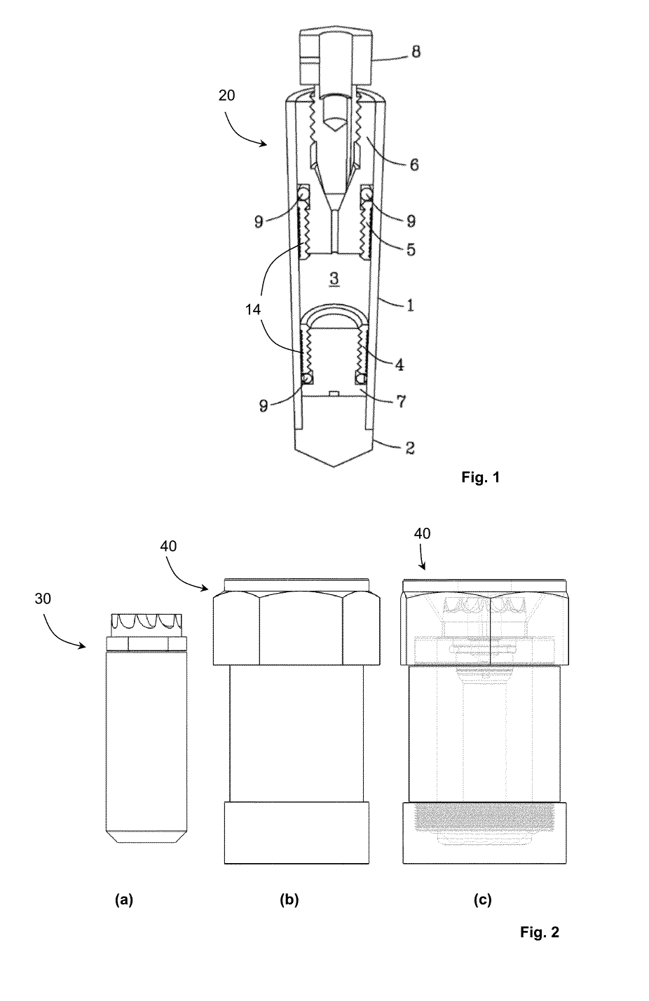

### DETAILED DESCRIPTION

FIG. 2 illustrates a sample holder 30 according to an embodiment (FIG. 2(a)) and a sealing cell 40 (FIG. 2(b)) used with the sample holder. The sealing cell is used seal the sample holder 30 and to accommodate filling of the sample holder 30, as described in further detail below. FIG. 2(c) illustrates the manner in which the sample holder 30 is retained in the sealing cell 40.

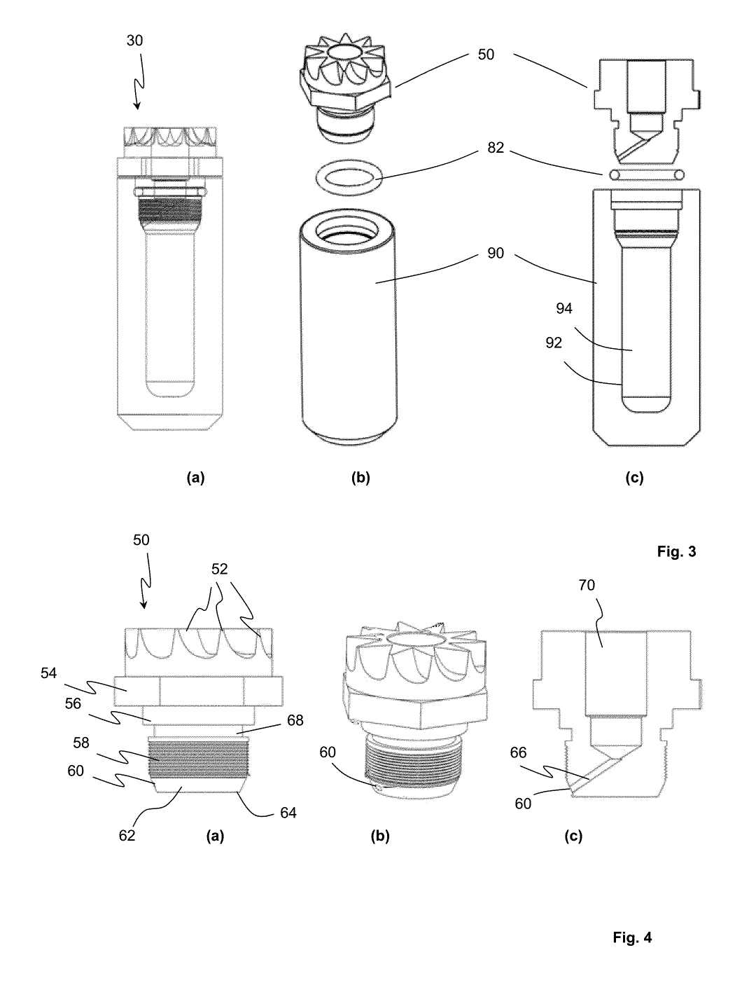

FIG. 3 illustrates an embodiment of the sample holder 30 of FIG. 2 in greater detail. The sample holder 30 (FIG. 3(a)) is shown in exploded view in FIGS. 3(b) and 3(c). As illustrated, the sample holder 30 comprises a plug 50, an O-ring 82 and a sample cell 90. The sample cell has an inner surface 92 which defines a sample volume 94 (FIG. 3(c)).

FIG. 4 illustrates an embodiment of the plug 50 in greater detail. Plug 50 is formed with rotor blades 52 used to drive rotation of the sample holder 30 in a known manner. A hexagonal (when viewed in axial plan) region 54 is formed between the blades 52 and a neck portion 56. Situated below the neck portion 56 is an annular depression 68. When the sample holder 30 is in use 0-ring 82 is situated in depression 68. The plug 50 further comprises a threaded portion 58 formed below the hexagonal portion 54. The threaded portion 58 joins the neck portion 56 to a tapered portion 62. The lower surface 64 of the tapered portion 62 forms the outer extremity of the plug 50 and constitutes the surface 64 with which a seal is formed, as described in greater detail below.

As illustrated in greater detail in FIGS. 4(b) and 4(c), the plug 50 comprises an aperture 60 formed in the tapered portion 62. The aperture 60 defines one of the openings of inlet 66. Referring to FIG. 4(c), the plug 50 includes a receptacle 70 formed in the upper part. The receptacle 70 accommodates an injector which is used to pressurize the sample volume 94 (FIG. 3). The inlet 66 opens into the receptacle 70 and therefore places the receptacle 70 in fluid communication with the aperture 60.

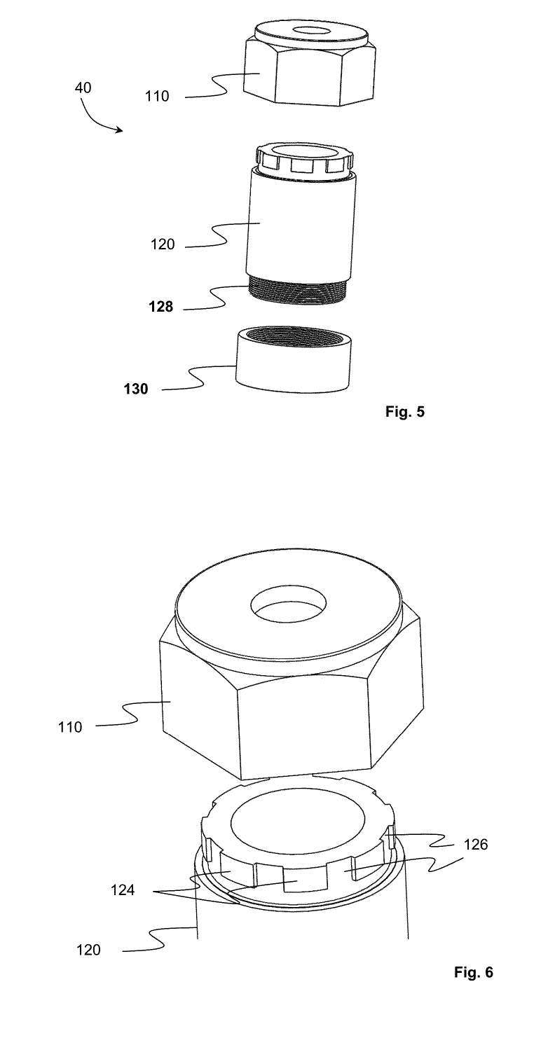

FIG. 5 illustrates an embodiment of the sealing cell 40 which includes a top cap 110, a sealing cylinder 120 and an end cap 130. The sealing cylinder 120 includes a lower threaded portion 128 which engages with a complimentary threaded portion in end cap 130.

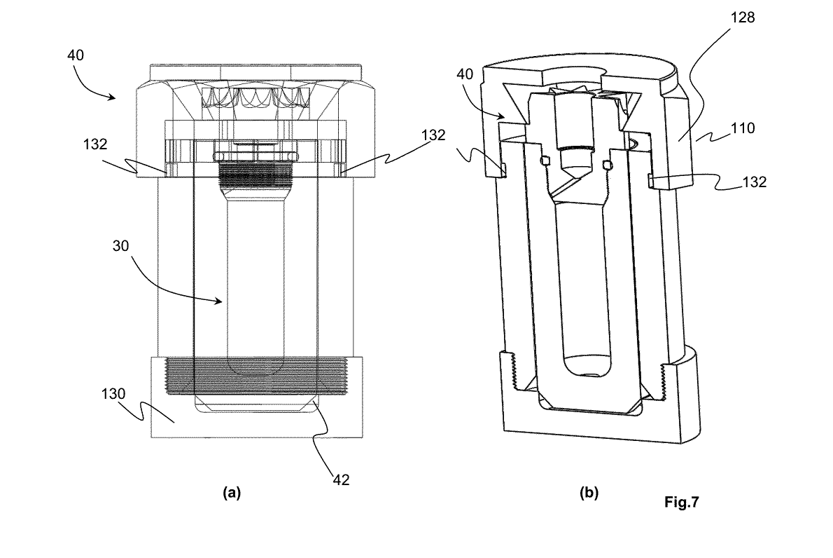

FIG. 6 illustrates a portion of the sealing cell 40. The portion of the sealing cylinder 120 which engages with the top cap 110 is formed with a plurality of abutments 124 which form channels 126 therebetween. The inside surface of top cap 110 is formed with two corresponding abutments 132 (FIG. 7) situated at opposed locations on the inside surface (not shown) which engage with the channels 126 and which are formed so that, when the top cap 110 is rotated relative to the sealing cylinder 120, the abutments of the top cap 110 are located behind the abutments 124, retaining the top cap 110 in place in a bayonet fitting.

FIGS. 7(a) and (b) illustrated the sample holder 30 inserted in the sealing cell 40. As illustrated in FIG. 7(a), a sealing O-ring 42 is located between the lower end of the sample holder 30 and the end cap 130.

As illustrated in FIG. 7(b), the top cap 110 of sealing cell 40 is formed with a hexagonal fitting 128 which corresponds to the hexagonal region 54 (FIG. 4) of the plug 50 of sample holder 30. Therefore, when the top cap 110 is rotated into place on sealing cylinder 120, the hexagonal fitting 128 engages with the hexagonal region 54 thereby rotating the plug 50 when the top cap 110 is rotated.

It is to be realized that the provision of a top cap (in the manner illustrated in FIG. 5) or an integrated bottom portion for the sample cell 90 (as illustrated in FIGS. 3 and 5) are not dependent on the particular embodiments illustrated and may be used interchangeably with these embodiments.

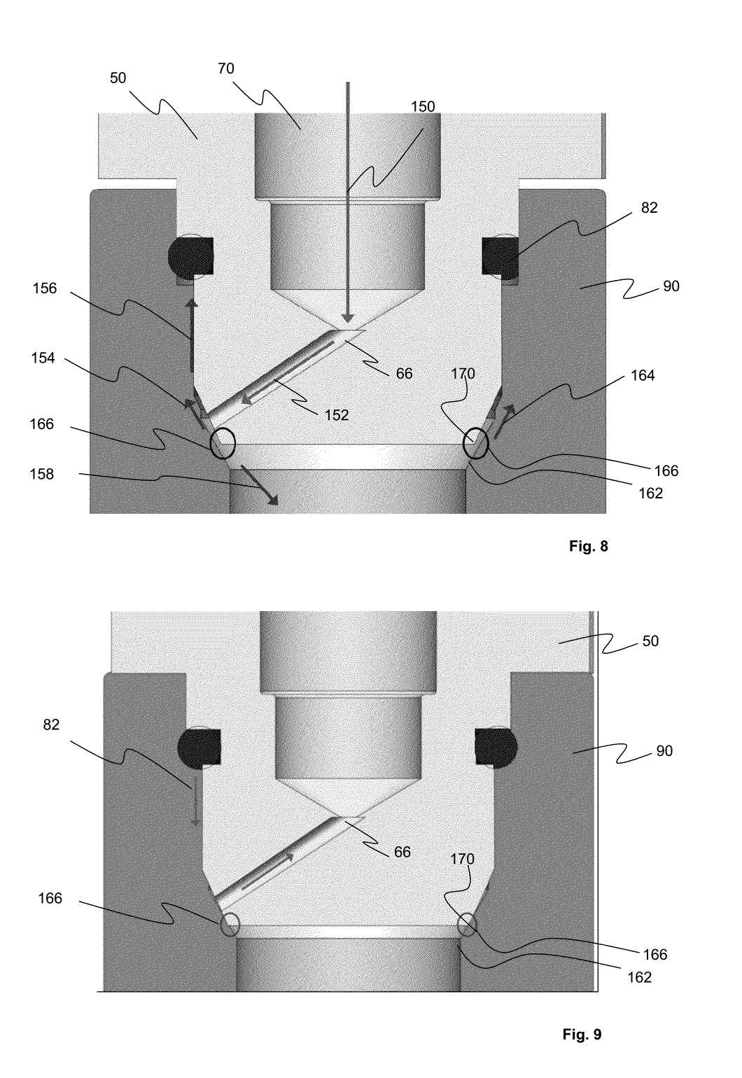

FIGS. 8 and 9 illustrate embodiments of operation of the sealing cell 40 and sample holder 30 of FIG. 2. The plug 50 includes receptacle 70 which accommodates an injector for delivering a pressurized fluid. (It is to be realized that the receptacle 70 also or instead accommodates a vacuum pump, depending on the changes which are desired to be brought about to the environment in the sample cell 90).

In the orientation illustrated in FIG. 8, the plug 50 has been partially screwed into the sample cell 90 so that a space exists between the lower extremity of plug 50 (with reference to the orientation of the Figures) and the corresponding engaging portion of the sample cell 90. As illustrated in regions 166 of FIG. 9, the sample cell 90 comprises a tapered portion 162 which engages with the lower extremity 170 of the plug 50.

The direction of fluid flow when a pressurized fluid is introduced via an injector is shown in FIG. 9. As depicted by arrow 150 the initial fluid flow is from the top of the plug 50 towards the bottom. The fluid flows from receptacle through the inlet 66 as depicted by arrow 152. Once the fluid exits the inlet, it flows through the space between the lower extremity 170 of the plug 50 and the tapered portion 162 of the sample cell 90. As illustrated, the fluid may then flow either in the direction of arrows 154 and 156 or in the direction of arrow 158.

During this loading of the sample holder (e.g., through the introduction of pressurized fluid to the sample holder), the flow of fluid in the direction of arrow 154 and 156 is prevented by the O-ring 82.

FIG. 9 illustrates the sample holder 30 in the closed configuration. In this configuration, the plug 50 has been screwed in all the way to the sample cell 90 by the appropriate rotation of the top cap 110 of the sealing cell so that the lower extremity 170 of the plug 50 engages with the tapered portion 162 of the sample cell 90, forming a seal for the sample volume 94.

The difference between the orientation shown in FIG. 9 and that shown in FIG. 8 is a 60° rotation of the plug 50 relative to the sample cell 90.

The seal formed between the plug and the sample cell 90 lies upstream of the seal formed by the O-rings 82 in the sense that fluid escaping from the sample volume must first pass the seal formed between the outer extremity 170 of the plug 50 and the tapered portion 162 of the sample cell 90 (the first seal) before passing the seal formed by the O-ring (the second seal).

The first seal serves to maintain the operating environment in the sample volume and this does not depend on the O-ring. Furthermore, the first seal is provided by the edge to surface engagement, which facilitates forming a more efficient and reliable seal. Since the second seal, involving the O-ring, is only in use during loading of the sample volume, it is relatively easy to tell when the seal has degraded and needs replacing. Since the O-ring is easily accessible, it is easy to replace.

In an embodiment, the sample cell 90 is made of Rexolite® (C-Lec Plastics Inc., Philadelphia, Pa., USA) a microwave compatible plastic, but other materials, such as other high compatibility plastic materials may be used. In an embodiment, the plug 50 is made of Torlon® (Solvay Plastics), but other materials such as other plastics may also be used. In an embodiment, the sealing cell 40 is made from nonmagnetic stainless steel, but other materials may be used, such as other nonmagnetic metallic alloys.

As illustrated, both the sample cell 90 and the plug 50 are constructed as single body components, machined from solid materials. In alternate embodiments, the parts may be molded as a single integral whole.

As a safety feature, the turbine blades 52 and the thread 58 (FIG. 4) may be orientated so that rotation of the sample holder 30 is in the same direction as tightening of the cap 50 relative to the sample cell 90.

It is to be realized that depending on the target working pressure and temperature, active volume requirements, MAS spinning frequency range and material's strength a trade between the wall thickness (of the various components illustrated), sample active volume and the maximum spinning frequency can be made.

In an embodiment pressure in excess of 5.0 MPa (100 bar) may be achieved for a 7.0 mm diameter rotor type sample holder while the spinning frequency reaches 5.0 kHz or more.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A sample holder, comprising:
a sample cell having an inner surface defining a sample volume; and
a plug configured to couple to the sample cell, the plug including:
a pressurization inlet;
a first sealing surface configured to mate with the sample cell to form an operational seal of the sample holder; and
a second sealing surface configured to mate with the sample cell to form a pressurizing seal of the sample holder.

2. The sample holder according to claim 1 wherein,
the plug is configured to move between a first position and a second position;
the first sealing surface is configured to sealingly mate with the sample cell when the plug is in the first position; and
the second sealing surface is configured to sealingly mate with the sample cell when the plug is in the second position.

3. The sample holder according to claim 2 wherein the inner surface of the sample cell comprises a threaded portion, an outer surface of the plug comprises a complimentary threaded portion, and movement of the plug comprises rotation.

4. The sample holder according to claim 3 wherein the pressurization inlet has an inlet aperture upstream of the threaded portion of the outer surface of the plug.

5. The sample holder according to claim 2 wherein the second sealing surface is configured to sealingly mate with the sample cell when the plug is in the first position.

6. The sample holder according to claim 5 wherein the sample cell and the plug are configured to couple together through a bayonet connection.

7. The sample holder according to claim 1 having an escape fluid flow for fluid exiting the sample holder through an aperture filled by the plug, wherein the second seal is situated downstream from the first seal with respect to the escape fluid flow.

8. The sample holder according to claim 1 wherein the first sealing surface is a surface of a body of the plug configured to mate with the inner surface of the sample cell.

9. The sample holder according to claim 1 wherein the plug comprises a body and the second sealing surface comprises an O-ring positioned on the plug body and configured to mate with the inner surface of the sample cell.

10. The sample holder according to claim 1 wherein a receptacle is formed in the plug.

11. The sample holder according to claim 1 wherein the sample cell is formed as a single machined part.

12. The sample holder according to claim 1 wherein a body of the plug is formed as a single machined part.

13. The sample holder according to claim 1 wherein the sample cell has a first aperture filled by said plug.

14. The sample holder according to claim 1 wherein the sample cell has a first aperture and a second aperture wherein the first aperture is filled by said plug.

15. A system, comprising:
a sample holder having:
a sample cell having an inner surface defining a sample volume; and
a plug configured to couple to the sample cell, the plug including:
a pressurization inlet;
a first sealing surface configured to mate with the sample cell to form an operational seal of the sample holder; and
a second sealing surface configured to mate with the sample cell to form a pressurizing seal of the sample holder; and
an injector configured to deliver a fluid under pressure to the sample volume via the pressurization inlet.

16. The system according to claim 15 wherein the plug includes a receptacle at least partially defined by a threaded portion of a surface of the plug, and the injector includes a complementary threaded portion to engaging with the threaded portion of the plug.

17. A method, comprising:
forming a pressurization seal between a pressurization-seal surface of a plug and a sample cell of a sample holder, an inner surface of the sample cell defining a sample volume;
pressurizing the sample cell via an inlet in the plug; and
forming an operational seal between an operational-seal surface of the plug and the sample cell.

18. The method according to claim 17, comprising moving the plug between a first position and a second position, wherein the operational seal is formed when the plug is in the first position and the pressurization seal is formed when the plug is in the second position.

19. The method according to claim 18, comprising providing the inner surface of the sample cell with a threaded portion and an outer surface of the plug with a complimentary threaded portion, wherein the moving of the plug comprises rotation.

20. The method according to claim 19 wherein the inlet is formed with an inlet aperture upstream of the threaded portion of the outer surface of the plug.

21. The method according to claim 18 wherein the pressurization seal is formed when the plug is in the first position.

22. The method according to claim 21 wherein the sample cell and the plug are coupled together through a bayonet connection.

23. The method according to claim 17 wherein fluid exiting the sample holder flows in an escape fluid flow, wherein the second seal is provided downstream from the first seal with respect to the escape fluid flow.

24. The method according to claim 17 wherein the operational seal is formed between a surface of a body of the plug and the inner surface of the sample cell.

25. The method according to claim 17 wherein the plug comprises a plug body and an O-ring positioned on the body of the plug, and the pressurization seal is formed between the O-ring and the inner surface of the sample cell.

26. The method according to claim 17 wherein the plug includes a receptacle.

27. The method according to claim 17, comprising forming the sample cell as a single machined part.

28. The method according to claim 17, comprising forming a body of the plug as a single machined part.
